(19) United States
(12) Patent Application Publication
(10) Pub. No.: US 2025/0006496 A1
(43) Pub. Date: Jan. 2, 2025

(54) REMOVING CONDUCTIVE MATERIAL FROM A PEDESTAL OF A SEMICONDUCTOR LID OUTSIDE OF AN AREA CONTACTING A DIE

(71) Applicant: ADVANCED MICRO DEVICES, INC., SANTA CLARA, CA (US)

(72) Inventors: CHIA CHUN MIAO, SANTA CLARA, CA (US); SUNGJUN IM, SANTA CLARA, CA (US); HIMANSHU A BAL, SANTA CLARA, CA (US)

(21) Appl. No.: 18/345,233

(22) Filed: Jun. 30, 2023

(51) Int. Cl. H01L 21/033; H01L 21/304; H01L 23/367

(52) U.S. Cl. CPC H01L 21/0337; H01L 21/3043; H01L 23/3675

(57) ABSTRACT

A method for forming a lid of a semiconductor assembly includes applying a mask to a surface of the lid to leave an area of the lid including a pedestal and wider than the pedestal included in the lid exposed. The method applies a thermally conductive material to the area of the surface of the lid that is exposed and removes at least a portion of the thermally conductive material from the surface of the lid.

### BACKGROUND

Reducing thickness of dies in a semiconductor assembly allows the semiconductor assembly to provide increased functionality. Thinner dies allow more components to be included in a semiconductor assembly, increasing overall performance. However, the increased number of thin dies in a semiconductor assembly increases heat generated during operation.

### BRIEF DESCRIPTION OF THE DRAWINGS

FIG. 1 shows an example semiconductor assembly with a conventional lid according to some implementations.

FIG. 2 shows a step in a conventional process for applying thermally conductive material to a pedestal according to some implementations.

FIG. 3 shows a mask applied to a lid including a pedestal according to some implementations.

FIG. 4 shows application of a thermally conductive material to a portion of a lid exposed by a mask according to some implementations.

FIG. 5 shows removal of a thermally conductive material from one or more portions of a lid according to some implementations.

FIG. 6 shows application of a mask and a thermally conductive material to a lid including a plurality of pedestals according to some implementations.

FIG. 7 shows removal of thermally conductive material from a lid including a plurality of pedestals according to some implementations.

FIG. 8A shows application of a barrier material to portions of a lid to which thermally conductive material has been removed according to some implementations.

FIG. 8B shows a lid in which thermally conductive material has not been removed and instead, barrier material is placed on the thermally conductive material to provide thermal and TIM isolation according to the present disclosure.

FIG. 9 is a cross-sectional diagram of an example integrated circuit device having a lid including a thermally conductive material according to some implementations.

FIG. 10 sets forth a lid without a pedestal in which thermally conductive material is removed according to techniques of the present disclosure.

FIG. 11 shows a lid with no pedestal having removed a portion of a thermal conductive material.

FIG. 12 is an example computing device according to some implementations.

FIG. 13 is a flow chart illustrating an example method for manufacturing a lid including one or more pedestals for a semiconductor assembly according to some implementations.

### DETAILED DESCRIPTION

As semiconductor technologies further advance, an increasing number of dies are included in a semiconductor assembly. While this increases functionality provided by a semiconductor assembly, the increased number of dies increases an amount of heat generated during operation. To aid with heat dissipation, a semiconductor assembly includes a lid covering dies included in the semiconductor assembly. The lid includes thermally conductive material in locations corresponding to locations of a die. The thermally conductive material facilitates heat flow between the die and the lid, allowing heat generated by a die to be dissipated through the lid.

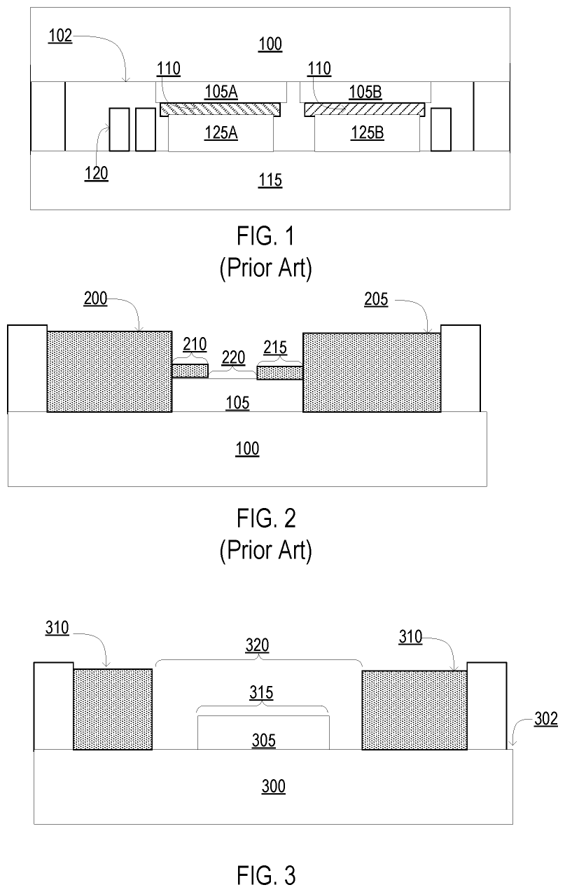

However, thin dies have a smaller height than conventional dies. This decreased height of a thin die causes a lid for a semiconductor assembly to include one or more pedestals. A pedestal increases a depth of the lid in one or more locations, allowing portions of the lid to extend lower and to contact a surface of a thin die. FIG. 1 shows an example semiconductor assembly with a conventional lid 100. The lid 100 has a first surface 102 nearest to a substrate 115. The lid 100 includes pedestals 105A, 105B in locations that correspond to locations on the substrate 115 where dies 125A, 125B are located. As shown in FIG. 1, a pedestal 105A, 105B increases a depth of the first surface 102 the lid, lowing the first surface 102 of the lid in one or more locations. Each pedestal 105A, 105B includes a layer of thermally conductive material 110 (for example, plating material). The thermally conductive material 110 contacts a surface of a die 125A, 125B and absorbs heat from the die 125A, 125B.

In conventional methods for fabricating a lid 100 including one or more pedestal 105A. 105B, a width of the pedestal 105A, 105B is constrained by processes for applying the thermally conductive material 110 to a pedestal 105A, 105B. FIG. 2 shows a step in a conventional process for applying thermally conductive material 110 to a pedestal 105. In the conventional process shown by FIG. 2, prior to application of the thermally conductive material 110, mask 200 and mask 205 are applied to the lid 100. Mask 200 and mask 205 prevent thermally conductive material 110 from being applied to portions of the lid 100 to which mask 200 and mask 205 are applied. As shown in FIG. 2, in a conventional process, portion 210 of mask 200 overlaps with a portion of the pedestal 105 and portion 215 of mask 205 overlaps with another portion of the pedestal 105. This prevents thermally conductive material 110 from being applied to the portion of the pedestal 105 covered by portion 210 of mask 200 and to the portion of the pedestal 105 covered by portion 215 of mask 205. This limits the application of the thermally conductive material 110 to location 220 of the pedestal 105. Accounting for the portion 210 of mask 200 and the portion 215 of mask 205 that overlap with the pedestal 105 increases a size of the pedestal 105. As shown in FIG. 2, despite thermally conductive material 110 being applied to location 220 of the pedestal 105, the overall width of the pedestal 105 is significantly larger than the location 220 where the thermally conductive material 110 is applied. For example, the width of a pedestal 105 is a sum of the width of the location 220 where the thermally conductive material 110 is applied (i.e., a width of a die 125A, 125B contacting the pedestal 105) and widths of the portion 210 of mask 200 and the portion 215 of mask 205.

Referring back to FIG. 1, the size of the pedestals 105A, 105B to accommodate application of the thermally conductive material 110 increases an amount of space occupied by portions of the pedestal that do not contact a surface of a die. The size of the pedestals 105A, 105B constrains a number of dies that can be included in a semiconductor assembly, as the size of the pedestals 105A, 105B reduces a space between adjacent pedestals 105A, 105B. To maintain at least a minimum spacing between pedestals 105A. 105B, a number of pedestals 105A, 105B capable of being included in a semiconductor assembly is limited by the size of the pedestals 105A, 105B for applying the thermally conductive material 110. Additionally, the size of the pedestals 105A, 105B from conventional techniques for thermally conductive material application reduces space between a pedestal and chip capacitors 120 in a semiconductor assembly. A chip capacitor 120 is a capacitor manufactured as an integrated circuit device that stores charge for use by dies 125A, 125B or other components of the semiconductor assembly. The reduced sized between pedestals 105A. 105B and chip capacitors 120 from the fabrication method described in conjunction with FIG. 2 limits a number of chip capacitors 120 capable of being included in a semiconductor assembly, reducing sources of charge available to dies 125A, 125B in the semiconductor assembly.

To reduce widths of pedestals included in lids for semiconductor assembly, masks are applied to a lid for a semiconductor assembly so the masks are wider than a width of a pedestal. Thermally conductive material is applied to portions of the lid that are not covered by the masks. After application, the thermally conductive material is removed from portions of the lid, leaving thermally conductive material in certain areas of the lid, while other areas of the lid do not have thermally conductive material. This application and removal of thermally conductive material allows the width of a pedestal to be reduced relative to conventional methods for application of thermally conductive material to a lid. Removing thermally conductive material from portions of the lid after application allows the thermally conductive material to be tailored to specific locations on the lid without covering portions of pedestals of the lid with a mask. Without having to be sized to accommodate portions of a mask for application of thermally conductive materials, pedestals of a lid are smaller, allowing spacing between pedestals to be increased without limiting a number of dies included in the semiconductor assembly.

To reduce widths of pedestals of a lid for a semiconductor, the present specification sets forth various implementations of a method for forming a lid of a semiconductor assembly that includes applying a mask to a surface of the lid to leave exposed an area of the lid including a pedestal and wider than the pedestal. The method further includes applying a thermally conductive material to the area of the surface of the lid that is exposed and removing at least a portion of the thermally conductive material from the surface of the lid. In some implementations, removing at least the portion of the thermally conductive material from the surface of the lid includes removing thermally conductive material from one or more portions of the surface of the lid that are outside of an area of the pedestal configured to contact a die. In some implementations, at least the portion of the thermally conductive material is removed from the surface of the lid using laser grooving, jetting, laser marking, and others. In some implementations, removing thermally conductive material from one or more portions of the surface of the lid that are outside of the area of the pedestal configured to contact a die includes removing the thermally conductive material from one or more portions of the pedestal outside of the area of the pedestal configured to contact the die. In various implementations, removing at least the portion of the thermally conductive material from the surface of the lid includes removing the thermally conductive material from portions of the lid other than the pedestal. In various implementations, the thermally conductive material is a metal.

In some implementations, the lid of the semiconductor assembly includes a plurality of pedestals, and applying the mask to the surface of the lid includes applying the mask to the surface of the lid to expose an area of the lid including the plurality of pedestals and wider than the plurality of pedestals. Removing at least the portion of the thermally conductive material from the surface of the lid includes removing the thermally conductive material from one or more portions of the lid that are not included in at least one pedestal of the plurality of pedestals in some implementations. In some implementations, removing at least the portion of the thermally conductive material from the surface of the lid includes removing the thermally conductive material from a portion of at least one pedestal that is not configured to contact a die.

The present specification also sets forth a method for forming a lid of a semiconductor assembly including applying a mask to a surface of the lid to leave exposed an area of the lid including a pedestal and wider than the pedestal included. The method further includes applying a thermally conductive material to the area of the surface of the lid that is exposed and applying a barrier material to a location including the thermally conductive material, the barrier material partitioning the location into a plurality of sub-locations. The barrier material is a non-conductive material in various implementations. In various implementations the location is a location on the pedestal, and each of the plurality of sub-location is on the pedestal.

In some implementations, the method further includes coupling a surface of a first die to one of the plurality of sub-locations on the pedestal. The method further includes coupling a surface of a second die to another of the plurality of sub-locations on the pedestal in some implementations.

The present specification also describes various implementations of a semiconductor assembly including a substrate and a die coupled to the substrate. The semiconductor assembly also includes a lid coupled to the substrate and enclosing the die. The lid includes a first area of exposed metal, a second area of exposed metal, and a pedestal with a surface. The surface of the pedestal includes an area of thermally conductive material and contacts a surface of the die. The first area of exposed metal of the lid has a roughness different from the roughness of the second area of exposed metal.

In some implementations, the semiconductor assembly includes a second die coupled to the substrate. In such implementations, the lid also includes a second pedestal having a surface that includes a second area of thermally conductive material in contact with a surface of the second die. In such implementations, the first area of exposed metal of the lid is between the pedestals.

In some implementations, the pedestal of the semiconductor assembly also includes sides that are substantially perpendicular to the surface of the pedestal. In such implementations, at least one side also includes thermally conductive material.

In some implementations of the semiconductor assembly, the area of the thermally conductive material of the surface of the pedestal is less than a total area of the surface of the pedestal. In such implementations, the first area of exposed metal is on the surface of the pedestal external to the area of the thermally conductive material.

In some implementations of the semiconductor assembly, the surface of the pedestal includes a second area of thermally conductive material and a non-conductive material separating the areas of thermally conductive material.

In some implementations, the semiconductor assembly also includes a chip capacitor coupled to the substrate and enclosed by the lid, the chip capacitor coupled to the die via one or more connections in the substrate. The semiconductor assembly includes an additional chip capacitor coupled to the substrate and enclosed by the lid, the additional chip capacitor coupled to the die via one or more connections in the substrate. In some implementations, the thermally conductive material was removed from one or more portions of the surface of the pedestal outside of an area of the surface of the pedestal configured to contact the die.

The following disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows include implementations in which the first and second features are formed in direct contact, and also include implementations in which additional features formed between the first and second features, such that the first and second features are in direct contact. Further, spatially relative terms, such as “beneath,” “below,” “lower,” “above,” “upper,” “back,” “front,” “top,” “bottom,” and the like, are used herein for ease of description to describe one element or feature's relationship to another element(s) or feature(s) as illustrated in the figures. Similarly, terms such as “front surface” and “back side” or “top surface” and “back side” are used herein to more easily identify various components, and identify that those components are, for example, on opposing sides of another component. The spatially relative terms are intended to encompass different orientations of the device in use or operation in addition to the orientation depicted in the figures.

FIGS. 3-5 show steps in an example manufacturing process for a lid 300 of a semiconductor assembly. As shown in FIG. 3, the lid 300 includes a pedestal 305 extending farther than a surface 302 of the lid 300. The surface 302 of the lid 300 is configured to be nearest to dies of the semiconductor assembly. The pedestal 305 of the lid 300 extends a depth of the lid 300 in the location of the pedestal 305, so the pedestal 305 extends closer to a substrate of the semiconductor assembly than the remaining portions of the lid 300 when the lid 300 is placed on the semiconductor assembly. Inclusion of the pedestal 305 allows the lid 300 to accommodate dies that are thinner than conventional dies. Because thinner dies have shorter heights, the pedestal 305 increases a depth of the lid 300, allowing the pedestal 305 to contact dies having shorter heights. In the example of FIG. 3, a surface of a die with a shorter height is capable of contacting the pedestal 305, allowing heat generated by the die during operation to be thermally transferred to the lid 300 via contact with the pedestal 305 and dissipated through the lid 300.

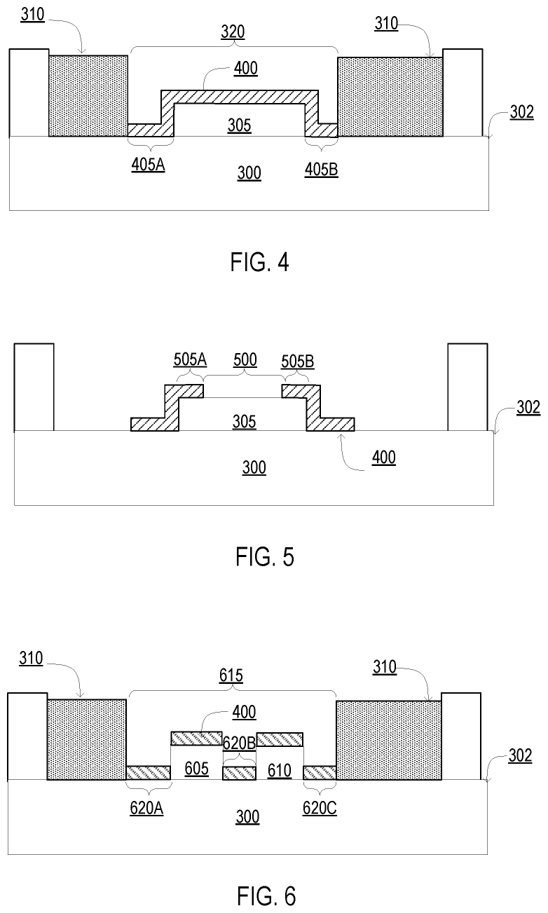

To facilitate heat transfer from a die to the lid 300, thermally conductive material is applied to portions of the lid 300. In various implementations, the thermally conductive material is applied to portions of the lid 300 configured to contact a die. The thermally conductive material improves heat transfer between the portions of the lid 300 configured to contact a die to allow the lid 300 to better absorb heat from the die, while heat transfer of other portions of the lid without the thermally conductive material is not altered. To apply thermally conductive material to the lid, a mask 310 is applied to portions of the lid 300. Thermally conductive material is not applied to portions of the lid 300 covered by the mask 310, while thermally conductive material is applied to portions of the lid 300 that are exposed by the mask 310, as further described below in conjunction with FIG. 4. In the example shown by FIG. 3, an area 320 of the lid 300 exposed when the mask 310 is applied includes the pedestal 305, with the area 320 of the lid that is exposed 305 including the pedestal 305 and wider than a width 315 of the pedestal 305. In contrast, the conventional method shown in FIG. 2 results in a location 220 where the thermally conductive material 110 is applied that is less than the width of a pedestal 105A, 105B, as portion 210 of mask 200 and portion 215 of mask 205 in FIG. 2 cover portions of the pedestal 105A, 105B, reducing an amount of the pedestal 305 that is exposed when the mask 310 and the mask 205 are applied.

As shown in FIG. 4, thermally conductive material 400 is applied to portions of the lid 300 that are exposed by the mask 310. In various embodiments, the thermally conductive material 400 is applied to the portions of the lid 300 exposed by the mask 310 through a plating process, such as electroplating. In various implementations, the thermally conductive material 400 is a metal. Example metals used for the thermally conductive material 400 include gold, copper, silver, tin, tin alloys, or other metals providing thermal conductivity. Because the mask 310 exposes an area 320 of the lid 300 that includes the pedestal 305 and is wider than the pedestal 305, the conductive material 400 is applied to the pedestal and also to portions 405A, 405B of the surface 302 of the lid 300. That is, the pedestal 305 includes sides that are substantially perpendicular to the surface of the pedestal and those sides include thermally conductive material.

After application of the thermally conductive material to the area 320 of the lid 300 exposed by the mask 310, the mask 310 is removed from the surface 302 of the lid 300. With the mask 310 removed, one or more portions of the thermally conductive material 400 are then removed, as shown in FIG. 5. In the example shown by FIG. 5, the thermally conductive material 400 is removed from portion 500 of the pedestal 305. In some implementations, the thermally conductive material 400 is removed through laser grooving, where a laser creates grooves in the thermally conductive material 400, and then subsequently removes the thermally conductive material 400 between the created edges. In other implementations, the thermally conductive material 400 is removed from a portion through other methods, such as grinding, chemical removal, jetting, laser marking, stripping, and the like. By removing the portion 500 of thermally conductive material from the pedestal, two separate portions 505A and 505B remain. In this way, the surface of the pedestal includes one or more areas of thermally conductive material that is less than a total area of the surface of the pedestal. Each of the portions 505A. 505B is thermally isolated from the other and enables thermal isolation when a separate die is in contact with each separate portion 505A, 505B. The removal of the portion 500 effectively operates as if a mask were utilized (in portion 500) during application of the thermally conductive material. However, masks have a limited width constraint and in some instances could not be utilized to create the portion 500. Additionally, the sides of the pedestal 305 in this example include thermally conductive material after the removal process. By contrast, traditional processes of apply thermally conductive materials to pedestals require that the mask be cover some area of the surface of the pedestal such that the sides of the pedestal could not be applied with thermally conductive material.

The 300 in the example of FIG. 5 includes various areas of exposed metal. In some implementations, the surface of the lid (including the surface of the pedestal) is plated with nickel or another metal prior to the application of the of the mask 310 and thermally conductive material 400. Areas of metal of the lid that are exposed after removal of thermally conductive material, such as the exposed area of metal in portion 500, have a different roughness than other areas of exposed metal of the lid, such as the areas of the lid that were masked 310 prior to removal. Roughness, also referred to as surface roughness, is a measure of deviations in the direction of a normal vector of a real surface from its ideal form. Said another way, roughness is a measure of irregulates on a surface of a metal. Roughness can be calculated either on a profile (line) or a surface (area). In the case of the profile roughness calculations, the roughness is often expressed as Ra, which is the is the arithmetic average of the roughness profile. Ra is a measurement of average of the peaks and valleys of a metal service over a sample length of the surface, based on deviation from a mean line. Such measurements can be taken with various instruments including a profilometer or laser scanner.

In some implementations, a lid may be plated with Nickel or a Nickel alloy and can be manufactured in such a ways to control the roughness (Ra) of the plating to under 0.5 μm. By contrast, when areas of such Nickel or Nickel alloys are exposed after removal of the thermally conductive material may have a roughness (Ra) of 1.0 μm or greater. That is, areas of the plating that are exposed by the removal of thermally conductive material may have a roughness that is double (or more) than that of areas of the same plating that are generally exposed (not due to removal of the thermal conductive material). Moreover, due to the high variance of surface roughness between the areas of metal exposed by removal of the thermally conductive material and other areas of the meal, the areas may be visually different in color. Often, areas of metal having greater surface roughness are significantly darker than those of lesser surface roughness.

In various implementations, a portion of the pedestal 305 is configured to contact a surface of a die, while remaining portions of the pedestal 305 do not contact the surface of the die. As shown in the example of FIG. 5, removal of the thermally conductive material accounts for one or more portions of the pedestal 305 that do not contact a die, limiting the thermally conductive material 400 to portion 500 of the pedestal 305, while the thermally conductive material 400 is removed from additional portions 505A, 505B of the pedestal 305. This allows the thermally conductive material 400 to remain in a portion 500 of the pedestal 305 configured to contact a die, improving heat transfer from the die to the pedestal 305 when the lid is applied to a semiconductor assembly, without excess thermally conductive material 400 in portions of the surface 302 of the lid that do not contact at least one die. Removing the thermally conductive material 400 after its application allows the lid 300 to include the thermally conductive material 400 in locations more specifically tailored to specific locations of dies in a semiconductor assembly. Removing the thermally conductive material 400 from locations of the lid 300 that do not contact a die allows the lid 300 to include thermally conductive material 400 in locations that are specific to dimensions of the die, reducing a likelihood of the thermally conductive material 400 being subject to reduction in heat transfer from voids formed from dispersion of the thermally conductive material 400 across a relatively large area of the lid 300.

While FIGS. 3-5 show steps in an example manufacturing process for a lid 300 including a single pedestal 305, the manufacturing process described above in conjunction with FIGS. 3-5 is also applicable to a lid 300 including a plurality of pedestals. FIG. 6 shows an example step in a manufacturing process for a lid 300 including a plurality of pedestals, pedestal 605 and pedestal 610. As shown in FIG. 6, the mask 310 is applied to the surface 302 of the lid 300 nearest to one or more dies. As further described above in conjunction with FIG. 3, the mask 310 prevents subsequent application of the thermally conductive material 400 to portions of the lid 300 covered by the mask 310, while the thermally conductive material 400 is applied to other portions of the lid 300 that are exposed by the mask 310. In the example shown by FIG. 6, an area 615 of the lid 300 exposed when the mask 310 is applied includes pedestal 605 and pedestal 610, with the area 615 of the lid 300 exposed by the mask 310 wider than a combined width of pedestal 605 and pedestal 610.

In conventional manufacturing methods, as further described above in conjunction with FIG. 2, portions 210, 215 of one or more masks 200, 205 cover portions of each pedestal 605, 610. Having a portion of a mask 200, 205 cover a portion of a pedestal 605, 610 causes an increased in a width of the pedestal 605, 610 to accommodate coverage by a portion of a mask 200, 205 while maintaining sufficient area of the pedestal 605, 610 for inclusion of thermally conductive material 400 to contact a die. This increase in pedestal size in a conventional manufacturing process reduces a number of pedestals 605, 610 that can be included on a lid, and reduces a number of components that can be included in a semiconductor assembly to prevent the components from contacting a pedestal 605, 610. Further, the increased size of pedestals 605, 610 in a conventional manufacturing process decreases spacing between pedestals in a conventional die, which reduces structural integrity of the lid 300.

In contrast, applying the mask 310 to the surface 302 of the lid 300 to expose an area 615 of the lid 300 including the plurality of pedestals 605, 610 and wider than a combined width of pedestal 605 and pedestal 610 allows widths of pedestal 605 and pedestal 605 to be smaller, as portions of the mask 310 do not cover portions of a pedestal 605, 610. With the mask 310 applied to the surface 302 of the lid 300, the thermally conductive material 400 is applied to the exposed area 615 of the surface 302 of the lid 300, as further described in conjunction with FIG. 4. As shown in FIG. 6, the thermally conductive material 400 is applied to pedestal 605 and to pedestal 610, as well as to portions 620A, 620B, 620C of the surface 302 of the lid 300 other than pedestal 605 and pedestal 610 that are within the exposed area 615.

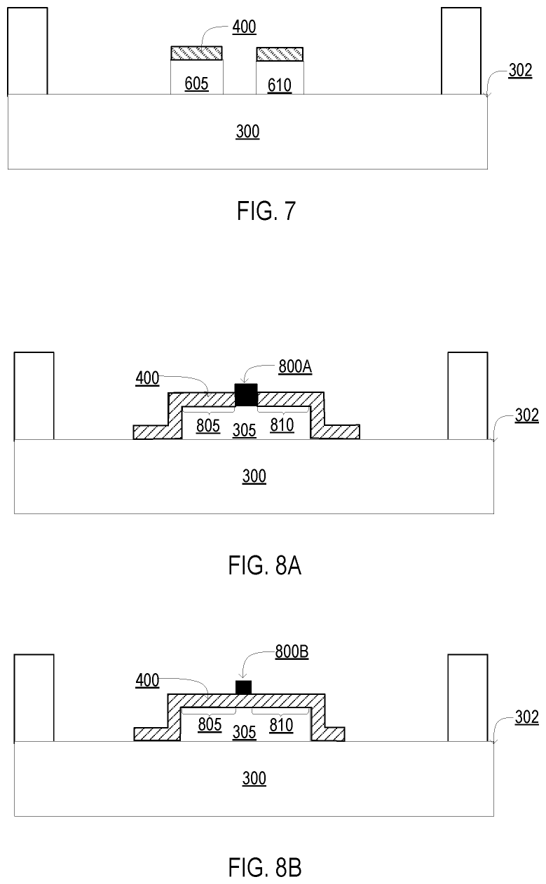

After application of the thermally conductive material 400 to the exposed area 615 of the surface 302 of the lid 300, the mask 310 is removed, and the thermally conductive material 400 is removed from portions of the surface 302 of the lid 300, as further described above in conjunction with FIG. 5. FIG. 7 shows an example where the thermally conductive material 400 is removed from portions of the surface 302 of the lid 300 other than pedestal 605 and pedestal 610. In the example of FIG. 7, the thermally conductive material 400 is removed from portions 620A, 620B, 620C of the surface 302 of the lid 300, with the thermally conductive material 400 remaining on pedestal 605 and pedestal 610. In some implementations, the thermally conducive material 400 is removed from one or more portions of a pedestal 605, 610. For example, the thermally conducive material 400 is removed from one or more portions of a pedestal 605, 610 that are not configured to contact a die. In the preceding example, the thermally conductive material 400 remains applied to a portion of a pedestal 605, 610 configured to contact a die, while the thermally conductive material 400 is removed from other portions of the pedestal 605, 610 that are not configured to contact the die. This allows the thermally conductive material 400 to specifically remain on one or more locations of the pedestal 605, 610 that are configured to contact a die. Reducing an area of a pedestal 605, 610 to which the thermally conductive material 400 is applied decreases a likelihood of the thermally conductive material 400 having voids from application to a larger area, which decreases an efficiency of the thermally conductive material 400 in absorbing heat generated from a die.

While FIG. 5 shows an implementation of the manufacturing process where portions of the thermally conductive material 400 are removed, in other implementations, a barrier material is added to portions of the thermally conductive material 400 to separate different portions of the thermally conductive material 400 that contact different dies. FIG. 8A shows an example step in the manufacturing process where a barrier material is added to between portions of thermally conductive material 400.

In the example shown by FIG. 8A, a barrier material 800A, which is a non-conductive material, is applied to a location on pedestal 305. Application of barrier material 800A to the location on pedestal 305 partitions the location into a plurality of sub-locations. That is, the barrier material provides additional thermal isolation between the sub-location 805 and sub-location 810 of the thermal conductive material. Additionally, in some implementations, the barrier material 800A extends above the surface of each of the sub-locations and provides TIM isolation between the two portions. In the example of FIG. 8A, application of barrier material 800A to the location on the pedestal 305 partitions the location into two sub-locations, sub-location 805 and sub-location 810. Partitioning the pedestal 305 by the barrier material 800A simplifies positioning of different dies to contact different locations on the pedestal 305 by defining sub-location 805 and sub-location 810.

In FIG. 8A, the barrier material is applied between the sub-locations of the thermally conductive material after the removal of a portion of the material, while in some other implementations, the barrier material is applied to the thermally conductive material itself without removing any plating. FIG. 8B shows a lid in which thermally conductive material has not been removed and instead, barrier material is placed on the thermally conductive material to provide thermal and TIM isolation according to the present disclosure. In FIG. 8B, instead of the portion 500 of thermally conductive material being removed as in FIG. 5, barrier material 800B is placed on the thermally consecutive material at the same location. The barrier material 800B, while less thermally isolating with respect to the sub-locations 805, 810 than removing the thermally conductive material continues to provide a degree of thermal isolation between dies contacting the sub-locations when the lid is installed on a chip. Additionally, the barrier material 800B provides TIM isolation between the two sub-locations.

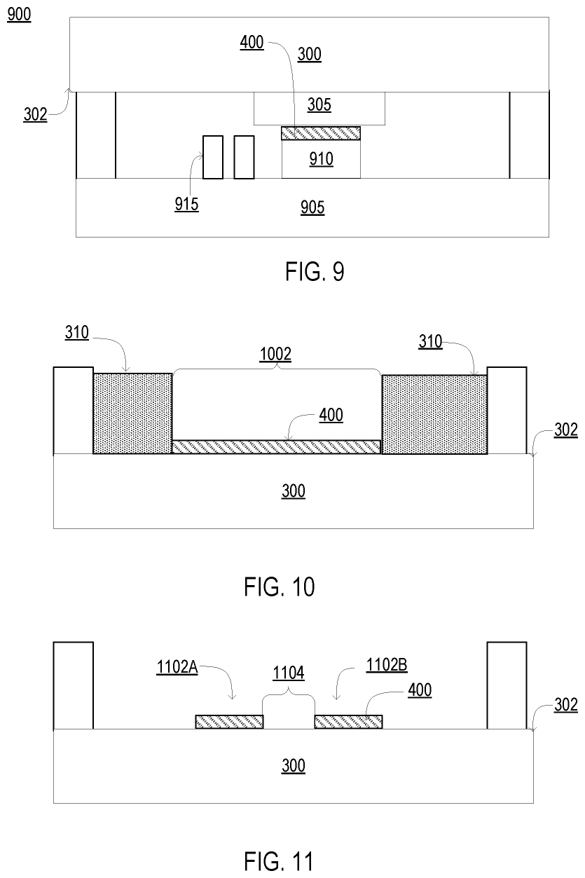

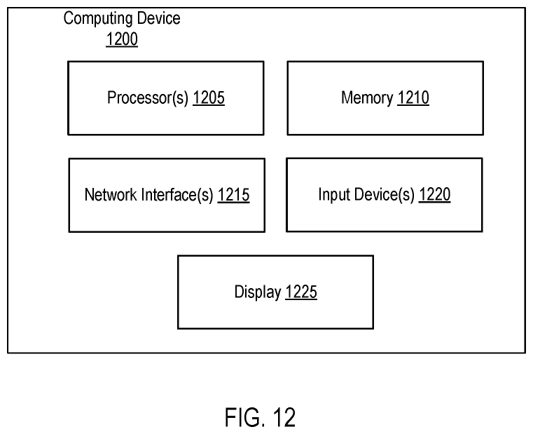

FIG. 9 is a cross-sectional diagram of an example integrated circuit device 900 including a semiconductor assembly having a lid 300 coupled to a substrate 905. The example integrated circuit device 900 can be implemented in a variety of computing devices, including mobile devices, personal computers, peripheral hardware components, gaming devices, set-top boxes, smart phones, and the like (as shown in FIG. 12). The example integrated circuit device 900 of FIG. 9 includes a die 910 that is coupled to a substrate 905. The substrate 905 is a portion of material that mechanically supports the die 910. In some implementations, the substrate 905 also electrically couples various components mounted to the substrate 905 via conductive traces, tracks, pads, and the like. For example, the substrate 905 electrically couples the die 910 to one or more other components via a solder bump (or another connector). In some implementations, the substrate 905 includes a printed circuit board (PCB), while in other implementations the substrate 905 is another semiconductor device, like the die 910 (which may include active components therein). In some implementations, the die 910 is coupled to the substrate 905 via a socket (not shown), where the die 910 is soldered to or otherwise mounted in the socket. In other implementations, as shown in FIG. 9, the die 910 is directly coupled to the substrate 905 via a direct solder connection or other connection as can be appreciated. In some implementations, the die 910 is coupled to the substrate 905 using a land grid array (LGA), pin grid array (PGA), or other packaging technology as can be appreciated.

The die 910 is a block of semiconducting material such as silicon onto which a functional integrated circuit is fabricated. As an example, the die 910 includes a processor such as a Central Processing Unit (CPU), a Graphics Processing Unit (GPU), or other processor as can be appreciated.

As an example, the die 910 includes a processor 1205 of a computing device 1200 as shown in FIG. 12. The computing device 1200 is implemented, for example, as a desktop computer, a laptop computer, a server, a game console, a smart phone, a tablet, and the like. In addition to one or more processors 1205, the computing device 1200 includes memory 1210. The memory 1210 includes Random Access Memory (RAM) or other volatile memory. The memory 1210 also includes non-volatile memory such as disk storage, solid state storage, and the like.

In some implementations, the computing device 1200 also includes one or more network interfaces 1215. In some implementations, the network interfaces 1215 include a wired network interface 1215 such as Ethernet or another wired network connection as can be appreciated. In some implementations, the network interfaces 1215 include wireless network interfaces 1215 such as Wi-Fi, BLUETOOTH®, cellular, or other wireless network interfaces 1215 as can be appreciated. In some implementations, the computing device 1200 includes one or more input devices 1220 that accept user input. Example input devices 1220 include keyboards, touchpads, touch screen interfaces, and the like. One skilled in the art will appreciate that, in some implementations, the input devices 1220 include peripheral devices such as external keyboards, mice, and the like.

In some implementations, the computing device 1200 includes a display 1225. In some implementations, the display 1225 includes an external display connected via a video or display port. In some implementations, the display 1225 is housed within a housing of the computing device 1200. For example, the display 1225 includes a screen of a tablet, laptop, smartphone, or other mobile device. In implementations where the display 1225 includes a touch screen, the display 1225 also serves as an input device 1220.

Referring to FIG. 9, a lid 300 is coupled to the substrate 905 on a side of the substrate 905 to which the die 910 is coupled. The lid 300 includes a pedestal 305 that is configured to contact a surface of the die 910. The lid 300 encloses the die 910 and other components coupled to the side of the substrate 905. For example, when multiple dies 910 are coupled to the side of the substrate, the lid 300 encloses the multiple dies 910. A thermally conductive material 400 is applied to a surface of the pedestal 305 configured to contact the die 910, as further described above in conjunction with FIGS. 3-8. The thermally conductive material 400 absorbs heat generated by the die 910 during operation, with the heat absorbed form the die transferred from the thermally conductive material 400 to the lid 300 via the pedestal 305. The lid 300 provides an increased surface area for the heat generated by the die 910, facilitating heat dissipation from the die 910. The lid is coupled to the substrate 905 through an adhesive in various implementations.

In some implementations, such as the implementation shown in FIG. 9, the integrated circuit device 900 includes one or more chip capacitors 915 couplet to the substrate 905. A chip capacitor 915 is a capacitor manufactured as an integrated circuit device that stores charge for use by the die 910 or by other components of the integrated circuit device 900. In various implementations, the chip capacitor 915 is coupled to the die 910 through one or more connections in the substrate 905, allowing the die 910 to access charge stored by the chip capacitor 915. Fabricating the lid 300 as further described above in conjunction with FIGS. 3-8 allows the pedestal 305 to be smaller (i.e., have a smaller width) than conventional manufacturing techniques, which allows for a greater number of chip capacitors 915 to be enclosed by the lid 300 and allows for chip capacitors 915 to be positioned closer to the die 910. Reducing distance between a chip capacitor 915 and a die 910 reduces latency in the die 910 obtaining charge from a chip capacitor 915.

FIG. 10 sets forth a lid without a pedestal in which thermally conductive material, such as plating, is removed according to techniques of the present disclosure. Some lids are utilized in packages in which no pedestal is required and, instead, thermally conductive material is placed on a surface of the lid and thermal interface material (TIM), which is often in liquid form, is applied on the surface of the thermally conductive material. A curing process is carried out after the TIM placement. TIM material deformation can occur after a realizability stress test. When the lid is placed on a chip, the thermally conductive material comes into contact with one or more dies of a chip with the TIM in between the dies and thermally conductive material. Readers will recognize that, although the thermally conductive material is said to “contact” a die here, such contact need not be direct contact, but, in many applications, there will be a layer of TIM between the two. Such a lid can be utilized for a variety of different chips with a variety of different die configurations. That is, a lid of one design may be utilized for a chip with a single die or with chips having multiple dies. A lid may be designed with an area of thermal conductive material to support multiple dies even if the lid is sometimes utilized with a chip having fewer dies than what the thermal conductive material can support. When a lid having an area of thermal conductive material large enough to support a number of dies is utilized to contact less than that number, there will be portions of the thermal conductive material that are exposed when the lid is placed on a chip. In this scenario, TIM is applied to areas of the thermal conductive material that will be in contact with a die when the lid is placed on the chip, but not to other areas of the thermally conductive material. In such a configuration the TIM material may become thinner in certain die area after a reliability stress test. Such thinning impacts thermal performance due to a loss of contact area. Additionally, after a package stress test in which temperature, electrical and/or humidity responses are tests, the TIM material in certain die area may become deteriorated. Isolated plating area for each die from such location will lower the risk of deformation of TIM material during and after package stress testing.

In FIG. 10, for example, a thermally conductive material 400 is applied to portions of the lid 300 that are exposed by the mask 310. In various embodiments, the thermally conductive material 400 is applied to the portions of the lid 300 exposed by the mask 310 through a plating process, such as electroplating. The area 1002 of the thermally conductive material is large enough to support multiple dies.

FIG. 11 shows a lid with no pedestal having removed a portion of a thermal conductive material. In the example shown by FIG. 11, the thermally conductive material 400 is removed from portion 1104 of the surface 302 of the lid 300. By removing the portion 1104 of thermally conductive material from the surface 302 of the lid 300, two separate portions 1102A and 1102B remain. Each of these portions is thermally isolated from the other and enables thermal isolation when a separate die is in contact with each separate portion 1102A, 1102B. Additionally, TIM can be applied to a single portion (e.g. portion 1102A) and when the lid is placed on a chip, a die contacting the portion will not cause the TIM to overflow onto the other portion (e.g. portion 1102B). The removal of the portion 1104 effectively operates as if a mask were utilized during application of the thermally conductive material. However, conventional masks have a limited width constraint and, in some instances, could not be utilized to create the portion 1104.

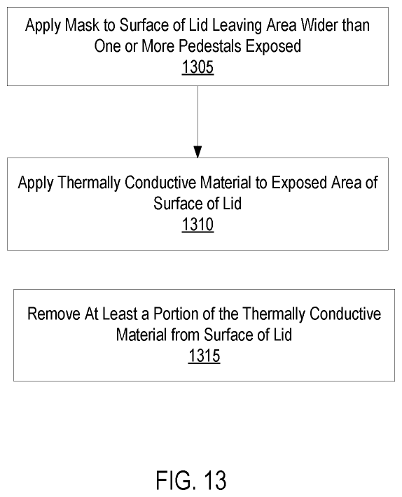

For further explanation, FIG. 13 sets forth a flow chart illustrating an example method for manufacturing a lid for a semiconductor assembly. The method shown in FIG. 13 includes applying 1305 a mask to a surface 302 of the lid 300 so an area of the lid 300 that includes a pedestal 305 and that is wider than the pedestal 305 is exposed. In implementations where the lid 300 includes a plurality of pedestals 605, 610, the mask is applied 1305 so the area of the lid 300 that is exposed includes the plurality of pedestals 605, 610 and is wider than a combined width of the plurality of pedestals 605, 610. In contrast, conventional methods apply a mask to the surface 302 of the lid so the mask covers portions of a pedestal 305 or covers portions of each of a plurality of pedestals 605, 610, causing an increase in width of pedestals to accommodate application of the mask to potions of a pedestal 305.

With the mask applied 305 to the surface 302 of the lid 300, the method applies 1310 a thermally conductive material 400 to the area of the surface 302 of lid 300 that is exposed. The thermally conductive material 400 is not applied to portions of the surface 302 of the lid 300 where the mask is applied. With the area of the surface 302 of the lid 300 wider than a pedestal 305 (or wider than a combined with of a plurality of pedestals 605, 610), the thermally conductive material 400 is applied to the pedestal 305 and to one or more portions of the lid 300 other than the pedestal 305. Similarly, when the lid 300 includes multiple pedestals 605, 610, application of the mask leaves an area wider than a combined width of the multiple pedestals 605, 610 and including the multiple pedestals 605, 610 exposed. Application of the thermally conductive material 400 to the area exposed from application of the mask causes application of the thermally conductive material 400 to the pedestals 605, 610 included in the area and to portions of the lid 300 other than the pedestals 605, 610.

The method removes the mask from the surface 302 of the lid 300 and removes 1315 at least a portion of the thermally conductive material 400 from the surface 302 of the lid 300. In some implementations, the thermally conductive material 400 is removed 1315 through laser grooving, while in other implementations the thermally conductive material 400 is removed 1315 using other suitable techniques (e.g., grinding). In some implementations, the thermally conductive material 400 is removed from portions of the surface 302 of the lid 300 other than the pedestal 305. In other implementations, the thermally conductive material 400 is removed from portions of the surface 302 of the lid 300 that are outside of an area of the pedestal 305 configured to contact a die 910. For example, the thermally conductive material 400 is removed from one or more portions of the pedestal 305 outside an area of the pedestal 305 configured to contact the die 910, limiting the thermally conductive material 400 to locations on the pedestal 305 that contact a die. In implementations where the lid 300 includes a plurality of pedestals 605, 610, the method removes 1315 the thermally conductive material 400 from portions of the surface 302 of the lid 300 that are not included in at least one pedestal 605, 610. Removing 1315 the thermally conductive material 400 from one or more portions of the surface 302 of the lid 300 limits the thermally conductive material 400 on the surface 302 of the lid 300 to locations where the lid 300 contacts a surface of a die or contacts another component on a substrate that generates heat. This allows the lid 300 to localize placement of the thermally conductive material 400 to areas that contact components generating heat, allowing the lid to absorb heat from one or more components, while reducing an area of the lid to which the thermally conductive material 400 is applied, which decreases a likelihood of voids in the thermally conductive material 400 reducing heat transfer to the thermally conductive material 400.

In other implementations, rather than remove 1315 at least a portion of the thermally conductive material 400 from the surface 302 of the lid 300, the method applies a barrier material to a location on the thermally conductive material 400, as described above in conjunction with FIG. 8B. Application of the barrier material partitions the location into a plurality of sub-locations. A surface of a die is capable of being coupled to one of the sub-locations, while a surface of another die is capable of being coupled to another sub-location. The barrier material is a non-conductive material in various implementations. Application of the barrier material allows a location including thermally conductive material to be divided into discrete locations for contacting different dies.

In view of the explanations set forth above, readers will recognize that manufacturing a lid for an integrated circuit device by applying a mask to the lid so an area wider than a pedestal of the lid is exposed and applying thermally conductive material to the exposed area of the lid allows the pedestal to have a smaller width than conventional methods. Removing the thermally conductive material from portions of the area other than the pedestal (or other than an area configured to contact a die) allows the thermally conductive material to be limited to areas contacting a die. As conventional methods apply the mask to portions of the pedestal, conventional pedestal widths are larger to accommodate placement of the mask to the portions of the pedestal, limiting a number of pedestals that can be included on the lid and limiting spacing between pedestals. Increasing application of the mask so an area wider than a pedestal is exposed allows the pedestal with to be smaller, allowing for greater spacing between pedestals for increased structural integrity or allowing for inclusion of a greater number of pedestals in the lid.

It will be understood from the foregoing description that modifications and changes can be made in various implementations of the present disclosure. The descriptions in this specification are for purposes of illustration only and are not to be construed in a limiting sense. The scope of the present disclosure is limited only by the language of the following claims.

What is claimed is:

1. A method for forming a lid of a semiconductor assembly comprising:
applying a mask to a surface of the lid to leave exposed an area of the lid including a pedestal and wider than the pedestal included in the lid;
applying a thermally conductive material to the area of the surface of the lid that is exposed; and
removing at least a portion of the thermally conductive material from the surface of the lid.

2. The method of claim 1, wherein removing at least the portion of the thermally conductive material from the surface of the lid comprises:
removing thermally conductive material from one or more portions of the surface of the lid that are outside of an area of the pedestal configured to contact a die.

3. The method of claim 2, wherein removing thermally conductive material from one or more portions of the surface of the lid that are outside of the area of the pedestal configured to contact a die comprises:
removing the thermally conductive material from one or more portions of the pedestal outside of the area of the pedestal configured to contact the die.

4. The method of claim 1, wherein removing at least the portion of the thermally conductive material from the surface of the lid comprises:
removing the thermally conductive material from portions of the lid other than the pedestal.

5. The method of claim 1, wherein the lid of the semiconductor assembly includes a plurality of pedestals, and wherein applying the mask to the surface of the lid comprises:
applying the mask to the surface of the lid to expose an area of the lid including the plurality of pedestals and wider than the plurality of pedestals.

6. The method of claim 5, wherein removing at least the portion of the thermally conductive material from the surface of the lid comprises:
removing the thermally conductive material from one or more portions of the lid that are not included in at least one pedestal of the plurality of pedestals.

7. The method of claim 5, wherein removing at least the portion of the thermally conductive material from the surface of the lid comprises:
removing the thermally conductive material from a portion of at least one pedestal that is not configured to contact a die.

8. The method of claim 1, wherein the portion of the thermally conductive material is removed from the surface of the lid using laser grooving.

9. The method of claim 1, wherein the thermally conductive material is a metal.

10. A method for forming a lid of a semiconductor assembly comprising:
applying a mask to a surface of the lid to leave exposed an area of the lid including a pedestal and wider than the pedestal included in the lid;
applying a thermally conductive material to the area of the surface of the lid that is exposed; and
applying a barrier material to a location including the thermally conductive material, the barrier material partitioning the location into a plurality of sub-locations.

11. The method of claim 10, wherein the barrier material comprises a non-conductive material.

12. The method of claim 10, wherein the location is a location on the pedestal, and each of the plurality of sub-locations is on the pedestal.

13. The method of claim 12, further comprising:
coupling a surface of a first die to one of the plurality of sub-locations on the pedestal.

14. The method of claim 13, further comprising:
coupling a surface of a second die to another of the plurality of sub-locations on the pedestal.

15. A semiconductor assembly comprising:
a substrate;
a die coupled to the substrate;
a lid coupled to the substrate and enclosing the die, the lid including:
a first area of exposed metal;
a second area of exposed metal; and
a pedestal with a surface, the surface of the pedestal including an area of thermally conductive material and contacting a surface of the die, wherein the first area of exposed metal has a roughness different from the roughness of the second area of exposed metal.

16. The semiconductor assembly of claim 15, further comprising a second die coupled to the substrate, wherein the lid further comprises:
a second pedestal having a surface that includes a second area of thermally conductive material in contact with a surface of the second die, wherein the first area of exposed metal is between the pedestals.

17. The semiconductor assembly of claim 15, wherein the pedestal further comprises sides substantially perpendicular to the surface of the pedestal and at least one side comprises thermally conductive material.

18. The semiconductor assembly of claim 15, wherein:
the area of the thermally conductive material of the surface of the pedestal is less than a total area of the surface of the pedestal; and
the first area of exposed metal is on the surface of the pedestal external to the area of the thermally conductive material.

19. The semiconductor assembly of claim 15, further comprising:
a chip capacitor coupled to the substrate and enclosed by the lid, the chip capacitor coupled to the die via one or more connections in the substrate.

20. The semiconductor assembly of claim 19, further comprising:
an additional chip capacitor coupled to the substrate and enclosed by the lid, the additional chip capacitor coupled to the die via one or more connections in the substrate.

21. The semiconductor assembly of claim 15, wherein the surface of the pedestal includes a second area of thermally conductive material and a non-conductive material separating the areas of thermally conductive material.
